(19) United States
(12) Patent Application Publication
(10) Pub. No.: US 2025/0379101 A1
(43) Pub. Date: Dec. 11, 2025

(54) SURFACE PASSIVATION FOR ACHIEVING CONTROLLABLE QUEUE TIME FOR POST-PLANARIZATION PROCESS

(71) Applicant: Tokyo Electron Limited, Tokyo (JP)

(72) Inventors: Kai-Hung Yu, Albany, NY (US); Ryota Yonezawa, Albany, NY (US); Hidenao Suzuki, Albany, NY (US); Takumi Nishinobo, Albany, NY (US)

(21) Appl. No.: 19/213,088

(22) Filed: May 20, 2025

Related U.S. Application Data
(60) Provisional application No. 63/656,552, filed on Jun. 5, 2024.

(51) Int. Cl. H01L 21/768; H01L 21/02; H01L 23/532

(52) U.S. Cl. CPC H01L 21/76834; H01L 21/02074; H01L 21/76825; H01L 21/76826; H01L 21/76828; H01L 23/53223; H01L 23/53238; H01L 23/53252; H01L 23/53266

(57) ABSTRACT

A method includes providing a substrate comprising a metal surface and a dielectric surface in at least substantially a same horizontal plane. The substrate is treated with a first inhibitor. The first inhibitor covers the metal surface. The substrate is treated with a second inhibitor. The second inhibitor covers the dielectric surface. The first inhibitor is removed from the metal surface of the substrate.

### CROSS-REFERENCE TO RELATED APPLICATIONS

This application claims the benefit of U.S. Provisional Application No. 63/656,552, filed on Jun. 5, 2024, which application is hereby incorporated herein by reference.

### TECHNICAL FIELD

The present disclosure relates generally to methods of processing a substrate, and, in particular embodiments, to methods for surface passivation for achieving a controllable queue time for a post-planarization process.

### BACKGROUND

In semiconductor manufacturing, copper interconnects are widely utilized in back-end-of-line (BEOL) metallization due to superior electrical conductivity and electromigration resistance compared to aluminum. The formation of these interconnects typically involves depositing copper in trenches and vias patterned in interlayer dielectric materials, followed by chemical mechanical polishing (CMP) to remove excess copper and planarize the surface. CMP processes employ slurries containing abrasives and chemical additives that facilitate material removal through combined mechanical abrasion and chemical reactions, resulting in a smooth surface suitable for subsequent processing steps.

As technology nodes advance toward smaller dimensions with metal pitches below 30 nanometers, maintaining the integrity of exposed copper surfaces following CMP becomes increasingly challenging. During the queue time between CMP and subsequent processing steps, copper may interact with atmospheric components such as oxygen and moisture, potentially leading to surface oxidation.

### SUMMARY

In accordance with an embodiment, a method includes: providing a substrate including a metal surface and a dielectric surface in at least substantially a same horizontal plane; treating the substrate with a first inhibitor, the first inhibitor covering the metal surface; treating the substrate with a second inhibitor, the second inhibitor covering the dielectric surface; and removing the first inhibitor from the metal surface of the substrate.

In accordance with another embodiment, a method includes: providing a substrate including a metal surface and a dielectric surface in at least substantially a same horizontal plane, the metal surface including an organic residue from a planarization process; removing the organic residue from the metal surface; forming a first passivation layer over the substrate, the first passivation layer covering the metal surface; forming a second passivation layer over the substrate, the second passivation layer covering the dielectric surface, where a first passivation layer covered metal surface and a second passivation layer covered dielectric surface prevent diffusion of oxidized metal from the metal surface onto the dielectric surface while waiting for further processing of the substrate; and removing the first passivation layer from the metal surface.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A-1H illustrate cross-sectional views of intermediate stages in the manufacturing of a semiconductor structure, in accordance with various embodiments;

FIG. 2 illustrates a process for forming a passivation layer on a dielectric surface, in accordance with various embodiments;

FIG. 3 illustrates a diagram showing a distribution of a leakage current along a semiconductor structure when no passivation layers are formed over metal and dielectric surfaces, in accordance with various embodiments;

FIG. 4 illustrates a diagram showing a distribution of a leakage current along a semiconductor structure when passivation layers are formed over metal and dielectric surfaces, in accordance with various embodiments;

FIG. 5 illustrates a diagram showing a distribution of a leakage current along a semiconductor structure when a passivation layer is formed over a dielectric surface, in accordance with various embodiments; and

FIG. 6 illustrates a flow diagram of a method for passivating a post-planarization surface, in accordance with various embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Surface passivation techniques described herein enable controllable queue time for post-chemical mechanical polishing (post-CMP) processes in back-end-of-line (BEOL) metallization. In various embodiments, methods for protecting a substrate having a metal surface and a dielectric surface in substantially the same horizontal plane involve the application of selective inhibitors to prevent metal diffusion and oxidation. A first inhibitor can selectively adsorb onto the metal surface, while a second inhibitor can cover the dielectric material surface, creating a protective environment that extends allowable queue time between processing steps.

In one or more embodiments, the surface passivation approach described herein addresses challenges associated with copper diffusion that commonly occurs within minutes or hours after CMP completion, particularly as metal pitch sizes decrease below 30 nm. The presence of moisture and hydroxyl termination on dielectric surfaces can act as oxidizing agents, causing oxidized copper to diffuse quickly onto adjacent dielectric materials. By applying appropriate inhibitors, the dielectric surface hydrophobicity increases, effectively reducing or blocking moisture and hydroxyl termination formation that facilitate copper diffusion.

The disclosed techniques can provide improvements in post-CMP queue time control, extending the safe processing window from hours to several days while maintaining acceptable leakage current levels. In various embodiments, the inhibitor-protected surfaces demonstrate leakage current improvements of up to two orders of magnitude compared to untreated surfaces. Additionally, the selective nature of the inhibitors enhances subsequent processes such as selective metal deposition for capping layers. The first inhibitor formed on the metal surface can be selectively removed while leaving the second inhibitor formed on the dielectric surface intact, enabling selective deposition on the exposed metal surface relative to the still-protected dielectric surface. In various embodiments, surfaces treated with both inhibitors maintain stable leakage current measurements for extended periods, in contrast to untreated surfaces that show rapid degradation after just two days. These and additional details are further discussed below.

While various embodiments of the present disclosure are described primarily in the context of copper interconnects in BEOL metallization processes, it should also be appreciated that these embodiments may also apply to other metal surfaces and semiconductor fabrication processes. In particular, aspects of this disclosure may similarly apply to alternative metals such as aluminum, tungsten, ruthenium, cobalt, nickel, tantalum, titanium, manganese, and molybdenum that may require surface protection between processing steps.

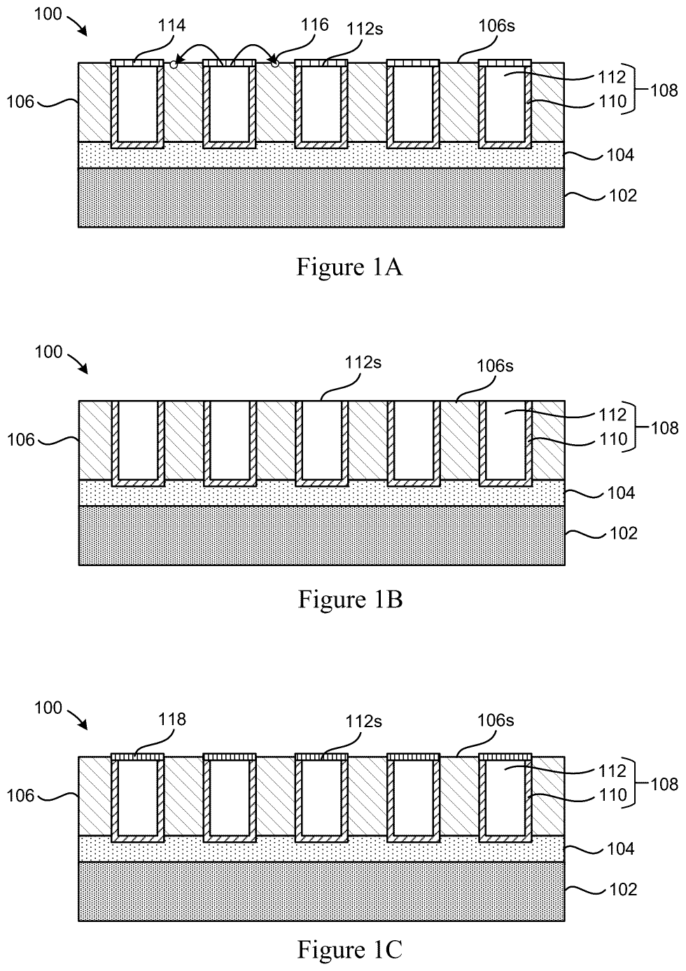

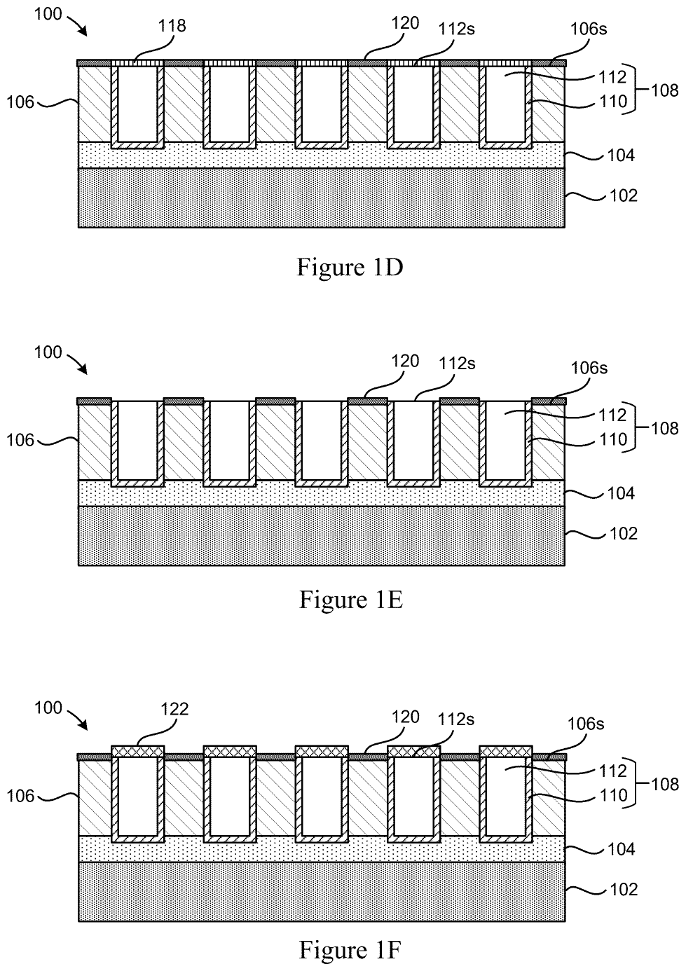

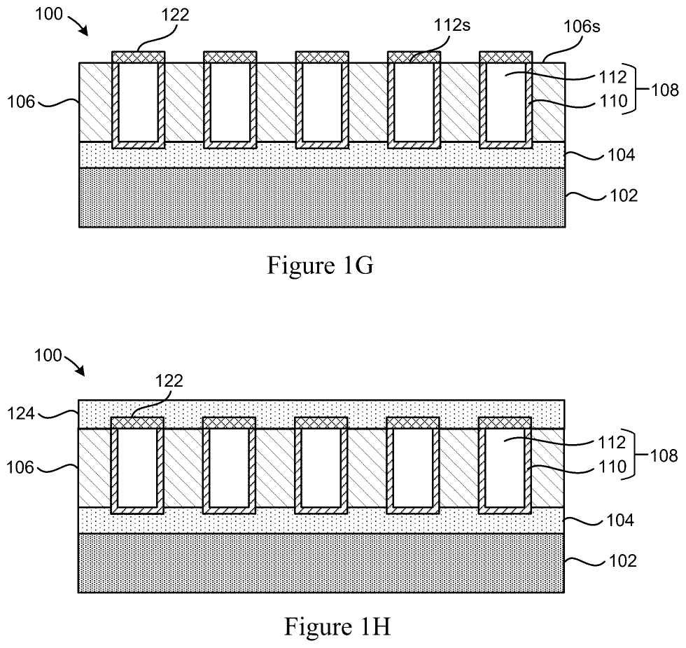

FIGS. 1A-1H illustrate cross-sectional views of intermediate stages in the manufacturing of a semiconductor structure 100, in accordance with various embodiments. Referring to FIG. 1A, in some embodiments, the semiconductor structure 100 includes a substrate 102, an etch stop layer 104, a dielectric layer 106 having a dielectric surface 106s, conductive features 108 (each comprising a barrier layer 110 and a metal layer 112) having a metal surface 112s.

In some embodiments, the substrate 102 may include a semiconductor material such as silicon, silicon germanium, silicon carbide, gallium arsenide, or other suitable semiconductor materials. In other embodiments, substrate 102 may comprise heterogeneous layers such as silicon germanium on silicon, gallium nitride on silicon, silicon carbon on silicon, or layers of silicon on a silicon or silicon-on-insulator (SOI) substrate. In various embodiments, the substrate 102 may include previously formed device structures such as transistors, capacitors, resistors, or other circuit elements formed during front-end-of-line (FEOL) processing. In such embodiments, the substrate 102 may include various doped regions, isolation structures, and other semiconductor components that form part of an integrated circuit.

The etch stop layer 104 is formed over the substrate 102 and may comprise silicon nitride, silicon carbide, silicon carbonitride, or other materials with suitable etch selectivity relative to the dielectric layer 106. The etch stop layer 104 may be formed using deposition techniques such as chemical vapor deposition (CVD), plasma-enhanced chemical vapor deposition (PECVD), atomic layer deposition (ALD), combinations thereof, or other suitable deposition methods.

The dielectric layer 106 is formed over the etch stop layer 104 and may comprise a low-k dielectric material having a dielectric constant less than that of silicon dioxide (SiO₂). In an embodiment, the dielectric layer 106 may comprise silicon dioxide, fluorinated silica glass, carbon-doped silicon oxide, porous silicon oxide, combinations thereof, or other suitable dielectric materials. The dielectric layer 106 may be formed using deposition techniques such as CVD, PECVD, ALD, combinations thereof, or other suitable deposition methods. The dielectric layer 106 has a dielectric surface 106s that may be exposed after subsequent processing steps.

The conductive features 108 are embedded within the dielectric layer 106 and may comprise a via, a line, or a combination thereof formed using damascene or dual damascene techniques. In one or more embodiments, the conductive features 108 may provide electrical connections to underlying conductive structures or devices in the substrate 102. In some embodiments, each of the conductive feature 108 comprises a metal layer 112 and a barrier layer 110 lining sidewalls and a bottom of the metal layer 112. The barrier layer 110 may comprise tantalum, tantalum nitride, titanium, titanium nitride, manganese, manganese nitride, niobium, niobium nitride, tungsten, tungsten nitride, combinations thereof, or the like. The barrier layer 110 may be formed using deposition techniques such as CVD, PECVD, ALD, combinations thereof, or other suitable deposition methods.

In various embodiments, the metal layer 112 may comprise copper, although other conductive materials such as aluminum, tungsten, cobalt, ruthenium, manganese, niobium or alloys thereof may also be used. The metal layer 112 provides the conductive path for electrical signals. The top surfaces (also referred to as metal surfaces 112s) of the metal layers 112 may be planarized using a chemical-mechanical polishing (CMP) process to be substantially level or coplanar with the dielectric surface 106s within process variations of the CMP process, forming a planarized surface of the semiconductor structure 100. After CMP processing, the metal layers 112 may be susceptible to oxidation and diffusion, which can lead to reliability issues in the semiconductor structure 100.

In some embodiments, during the CMP process used to planarize the semiconductor structure 100, organic compounds such as 1,2,3-benzotriazole (BTA) may be used as corrosion inhibitors in the CMP slurry. After completion of the CMP process, these organic compounds may remain on the metal layers 112 and form the organic residue layers 114. In various embodiments, the organic residue layers 114 comprises BTA molecules that adsorb onto the metal surfaces 112s through coordination bonds with the metal atoms, rendering the metal surfaces 112s hydrophobic. The thickness of the organic residue layers 114 may range from a few Å to 20 Å.

In some embodiments, an oxidized metal material 116 is formed when exposed metal at the metal surfaces 112s reacts with oxygen in the environment. In embodiments where the metal layers 112 comprises copper, the oxidized metal material 116 may comprise copper oxides such as Cu₂O, CuO, or a combination thereof. The presence of moisture and hydroxyl (—OH) termination on the adjacent dielectric surface 106s can accelerate the formation of the oxidized metal material 116. Once formed, the oxidized metal material 116 has increased mobility compared to non-oxidized metal and can diffuse laterally onto the dielectric surface 106s.

The diffusion of the oxidized metal material 116 onto the dielectric surface 106s presents challenges for queue time control in semiconductor manufacturing. This diffusion can happen within minutes or hours after the CMP process completion, particularly when the metal pitch is 30 nm or smaller. The migrated metal species can lead to increased leakage current between adjacent conductive features 108 and adversely affect the performance and reliability of the semiconductor structure 100. Additionally, the presence of the organic residue layers 114 and diffused metal species can interfere with subsequent processes, such as selective metal deposition for forming capping layers.

In FIG. 1B, the organic residue layers 114 (see FIG. 1A) are removed from the semiconductor structure 100. In various embodiments, the removal of the organic residue layers 114 is performed using a cleaning process that may include an anneal process. The anneal process may comprise exposing the semiconductor structure 100 to a gas mixture comprising hydrogen (H₂) and an inert gas such as argon (Ar), or to a gas mixture comprising nitrogen (N₂) and ammonia (NH₃). The anneal temperature may range from 200° C. to 300° C., and the process duration may range from 30 seconds to 3 minutes.

The anneal process removes the organic residue layers 114 from the metal layers 112, making the metal surfaces 112s susceptible to oxidation and migration onto the adjacent dielectric surface 106s. Without proper passivation, oxidized metal species may rapidly diffuse from the metal layers 112 onto the dielectric layer 106, which can cause increased leakage current and reliability issues.

In FIG. 1C, a passivation layer 118 is formed over the semiconductor structure 100 and covers the metal surfaces 112s. In various embodiments, the passivation layer 118 comprises a first inhibitor that selectively adsorbs onto the metal surfaces 112s while having reduced interaction with the dielectric surface 106s. The first inhibitor may include a small molecular inhibitor (SMI) or a precursor for a self-assembled monolayer. The first inhibitor may comprise nitrogen-containing compounds, non-heterocyclic carbenes, thiols, combinations thereof, or the like. In some embodiments, the nitrogen-containing compound comprises NH₃, N₂H₄, an aromatic compound, combinations thereof, or the like. Examples of nitrogenous aromatic compounds include pyridine having a chemical structure

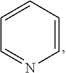

pyrimidine having a chemical structure

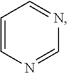

pyrazine having a chemical structure

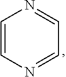

pyrrole having a chemical structure

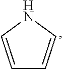

imidazole having a chemical structure

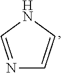

pyrazole having a chemical structure

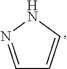

aniline having a chemical structure

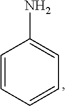

benzenethiol having a chemical structure

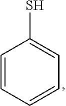

BTA having a chemical structure

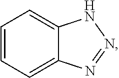

molecules that have strong affinity for metal surfaces, combinations thereof, or the like.

Examples of the non-heterocyclic carbenes include compounds having the following chemical structures:

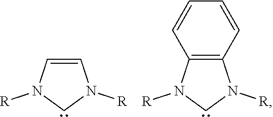

where R may comprise hydride groups, methyl groups, ethyl groups, iso-propyl groups (having less than three carbon atoms), or the like.

In other embodiments, the first inhibitor may comprise R—PO₃H, R—COOH, R—SH, R—SOₓ, combinations thereof, or the like, where R may comprise methane, ethane, propane, butane, methene, propene, benzene, or the like. In yet other embodiments, the first inhibitor may comprise 1-octadecanethiol (CH₃(CH₂)₁₆CH₂SH), perfluorodecyltrichlorosilane (CF₃(CF₂)₇CH₂CH₂SiCl₃), perfluorodecanethiol (CF₃(CF₂)₇CH₂CH₂SH), chlorodecyldimethylsilane (CH₃(CH₂)₈CH₂Si(CH₃)₂Cl), tertbutyl(chloro)dimethylsilane ((CH₃)₃CSi(Cl)(CH₃)₂)), combinations thereof, or the like.

In various embodiments, any suitable molecular inhibitor may be used, where it satisfies the following criteria: the first inhibitor adsorbs on a metal surface 112s selectively to other surfaces (e.g., dielectric surface 106s); and the metal surface 112s may be regenerated by a later removal step for the first inhibitor. In one or more embodiments, the first inhibitor may be oxygen-free to prevent any chance of oxygen interacting with the metal and cause impurity issues.

In some embodiments, the passivation layer 118 may be formed by exposing the semiconductor structure 100 to a vaporized first inhibitor compound diluted in a carrier gas such as nitrogen (N₂) or argon (Ar). The substrate temperature during the formation process may range from 100° C. to 300° C., and the process duration may range from 10 seconds to 3 minutes. In other embodiments, the passivation layer 118 may be formed by exposing the semiconductor structure 100 to a first inhibitor compound in a liquid form (e.g., as a part of a solution). In an embodiment, the passivation layer 118 forms through coordination bonds between nitrogen atoms in the inhibitor molecules and metal atoms at the metal surfaces 112s. The thickness of the passivation layer 118 may range from a few Å to 20 Å.

In some embodiments when the first inhibitor comprises pyridine, pyrimidine, pyrrole, aniline, or benzenethiol, the passivation layer 118 may be formed by exposing the semiconductor structure 100 to a vaporized first inhibitor compound diluted in a carrier gas such as nitrogen. In other embodiments when the first inhibitor comprises pyrazine, imidazole, pyrazole, or BTA, the passivation layer 118 may be formed by exposing the semiconductor structure 100 to a first inhibitor compound in a liquid form (e.g., as a part of a solution).

In some embodiments, the passivation layer 118 may protect the metal surfaces 112s from oxidation and prevent diffusion of metal species onto the adjacent dielectric surface 106s. In one or more embodiments, the passivation layer 118 is configured to be selectively removable in subsequent processing steps to allow for further metal deposition or other treatments while leaving other passivation layers intact.

In FIG. 1D, a passivation layer 120 is formed over the semiconductor structure 100 and covers the dielectric surface 106s. The passivation layer 120 comprises a second inhibitor that selectively adsorbs onto the dielectric surface 106s while being prevented from adsorbing onto the metal surfaces 112s by the presence of the previously formed passivation layer 118. In some embodiments, the molecules of the second inhibitor chemically bond to the dielectric surface 106s through reactions with surface hydroxyl groups (—OH), replacing hydrophilic hydroxyl terminations with hydrophobic groups. The thickness of the passivation layer 120 may range from a few Å to 20 Å.

In various embodiments, the second inhibitor may include a second small molecular inhibitor (SMI) or a precursor for a self-assembled monolayer that specifically targets dielectric surfaces. The second inhibitor may comprise a compound such an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, dimethylsilane dimethylamine (DMSDMA), trimethylsilane dimethylamine (TMSDMA), bis(dimethylamino) dimethylsilane (BDMADMS), N,O bistrimethylsilyltrifluoroacetamide (BSTFA), trimethylsilyl-pyrrole (TMS-pyrrole), combinations thereof, or the like.

In some embodiments, the passivation layer 120 can be formed by exposing the semiconductor structure 100 to a vaporized second inhibitor compound, which may be diluted in a carrier gas such as nitrogen (N₂) or argon (Ar). The substrate temperature during the formation process may range from 100° C. temperature to 300° C., and the process duration may range from 30 seconds to 3 minutes. In other embodiments, the passivation layer 120 may be formed by exposing the semiconductor structure 100 to a second inhibitor compound in a liquid form (e.g., as a part of a solution).

In some embodiments, the passivation layer 120 may render the dielectric surface 106s hydrophobic, which reduces or prevents moisture accumulation and the formation of hydroxyl terminations that can accelerate metal oxidation and diffusion. In conjunction with the passivation layer 118, the passivation layer 120 helps creating a dual protection system that reduces or prevents diffusion of oxidized metal species from the metal surfaces 112s onto the dielectric surface 106s during queue time between processing steps. In some embodiments, the dual passivation approach allows for extending the allowable queue time for the semiconductor structure 100.

In FIG. 1E, the passivation layer 118 (see FIG. 1D) is selectively removed from the metal surfaces 112s while maintaining the passivation layer 120 on the dielectric surface 106s. In various embodiments, the selective removal of the passivation layer 118 is performed using a hydrogen-containing anneal process. This process may comprise exposing the semiconductor structure 100 to a gas mixture containing hydrogen (H₂) at a temperature ranging from 200° C. to 300° C. for a duration ranging from 30 seconds to 3 minutes. The hydrogen-containing anneal selectively removes the passivation layer 118 from the metal surfaces 112s while leaving the passivation layer 120 on the dielectric surface 106s substantially intact due to the different chemical bonding mechanisms of the two passivation layers.

The selective removal of the passivation layer 118 exposes the clean metal surfaces 112s, making them available for subsequent processing such as selective metal deposition. In some embodiments, the hydrogen-containing anneal process may not only remove the passivation layer 118 but may also reduce any oxidized metal species that may have formed at the metal surfaces 112s, allowing for clean and reactive metal surfaces 112s for subsequent steps.

The combination of the exposed metal surfaces 112s and the protected dielectric surface 106s (still covered by passivation layer 120) allows for selective deposition processes. The passivation layer 120 continues to reduce or prevent moisture accumulation and hydroxyl termination formation on the dielectric surface 106s, reducing or blocking potential reaction sites for metal deposition chemistry and enhancing selectivity in subsequent metal deposition steps.

In FIG. 1F, a capping layer 122 is formed on the exposed metal surfaces 112s. In various embodiments, the capping layer 122 is selectively formed on the exposed metal surfaces 112s while the passivation layer 120 reduces or prevents deposition on the dielectric surface 106s. The capping layer 122 may comprise ruthenium, cobalt, nickel, molybdenum, tungsten, or other suitable metals that can improve the electromigration resistance of the underlying metal layers 112. In an embodiment where the metal layers 112 comprises copper, the capping layer 122 may comprise ruthenium (Ru).

The formation of the capping layer 122 may be accomplished using a CVD process, where a metal-containing precursor selectively reacts at the metal surfaces 112s. For ruthenium deposition, a precursor such as ruthenium carbonyl (Ru₃(CO)₁₂) may be used with a carbon monoxide (CO) carrier gas. The selective deposition process may be performed at a temperature ranging from 100° C. to 250° C. for a duration ranging from 5 seconds to 3 minutes, depending on the desired thickness of the capping layer 122.

In various embodiments, the capping layer 122 reduces or prevents diffusion of the metal layer 112 into subsequently formed layers, enhances electromigration resistance of the conductive feature 108, and reduces contact resistance for connections to upper metal levels. Additionally, the capping layer 122 may protect the metal layers 112 from oxidation during subsequent processing steps. The selective formation of the capping layer 122 on the metal surfaces 112s helps maintaining electrical isolation between adjacent conductive features 108, which allows for preventing leakage currents and short circuits in the semiconductor structure 100.

In FIG. 1G, the passivation layer 120 is removed from the semiconductor structure 100 to expose the dielectric surface 106s. In various embodiments, the removal of the passivation layer 120 may be performed using an ultraviolet (UV) radiation treatment, a plasma treatment, a combination thereof, or the like. The UV radiation treatment may comprise exposing the semiconductor structure 100 to UV light with wavelengths ranging from 10 nm to 380 nm for a duration ranging from 30 seconds to 3 minutes.

The plasma treatment may utilize oxygen, nitrogen, or ammonia plasma at low power settings or low temperature ambient to avoid damaging the underlying dielectric layer 106. In some embodiments, these treatments effectively break down and remove the passivation layer 120 from the dielectric surface 106s without adversely affecting the capping layer 122 or other components of the semiconductor structure 100.

In FIG. 1H, an etch stop layer 124 is formed over the exposed dielectric surface 106s and the capping layer 122. In some embodiments, the etch stop layer 124 may be formed using similar materials and methods as the etch stop layer 104 described above with reference to FIG. 1A, and the description is not repeated herein. In some embodiments, the formation of the etch stop layer 124 represents the completion of one metallization level in the semiconductor structure 100, preparing the structure for the next level of metallization. The next level of metallization may be formed in a similar manner as the previous metallization layer.

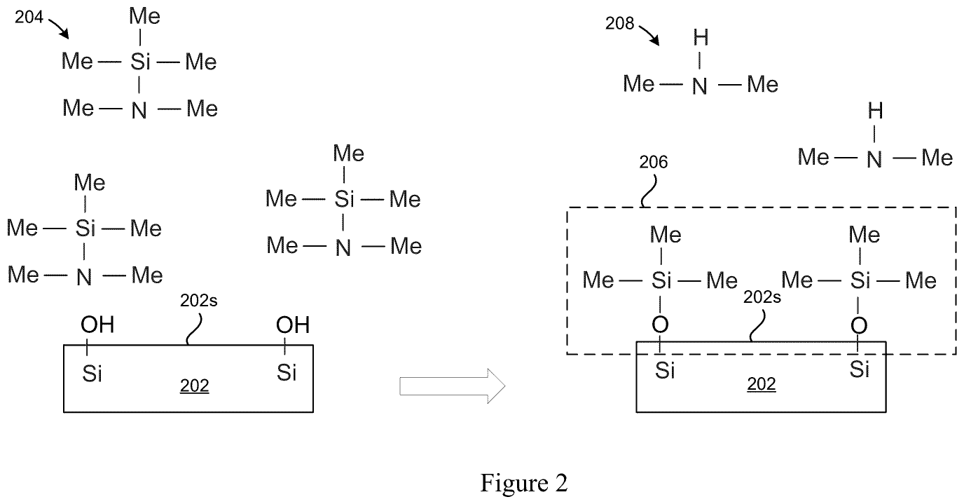

FIG. 2 illustrates a process for forming a passivation layer 206 on a dielectric surface 202s, in accordance with various embodiments. In particular, the illustrated embodiment depicts a chemical reaction between trimethylsilane dimethylamine (TMSDMA) molecules 204 and hydroxyl groups (—OH) present on the dielectric surface 202s of a dielectric material 202.

The dielectric material 202 may comprise silicon dioxide (SiO₂), a low-k dielectric material, or other suitable dielectric materials used in semiconductor structures. The dielectric surface 202s is characterized by the presence of silanol groups (Si—OH) that provide reactive sites for the passivation process. These hydroxyl terminations on the dielectric surface 202s can accelerate metal oxidation and diffusion when in proximity to metal features. In some embodiments, the modification of hydroxyl terminations allows for controlling queue time.

A TMSDMA molecule 204 comprises of a silicon atom bonded to three methyl groups (SiMe₃) and a dimethylamine group (NMe₂). In various embodiments, the TMSDMA molecules 204 are delivered as a vapor to the dielectric surface 202s, and may be diluted in a carrier gas such as nitrogen (N₂) at a substrate temperatures ranging from 100° C. to 250° C.

A chemical reaction occurs when a TMSDMA molecule 204 approaches the hydroxyl groups on the dielectric surface 202s. The nitrogen atom in the dimethylamine group forms a coordination bond with the hydrogen of the hydroxyl group, facilitating the reaction. The silicon-nitrogen bond in the TMSDMA molecule 204 then breaks, allowing the trimethylsilyl group to bond with the oxygen atom of the hydroxyl group. This reaction results in the formation of the passivation layer 206 on the dielectric surface 202s and the release of a volatile compound 208 such as HNMe₂.

The resulting passivation layer 206 comprises of trimethylsilyl groups (—SiMe₃) covalently bonded to the oxygen atoms on the dielectric surface 202s. This transforms the originally hydrophilic dielectric surface 202s into a hydrophobic surface due to the presence of the methyl groups. In an embodiment, the passivation layer 206 has a thickness ranging from 1 Å to 5 Å, forming a continuous layer that allows for reducing or blocking moisture and reducing or preventing hydroxyl group formation.

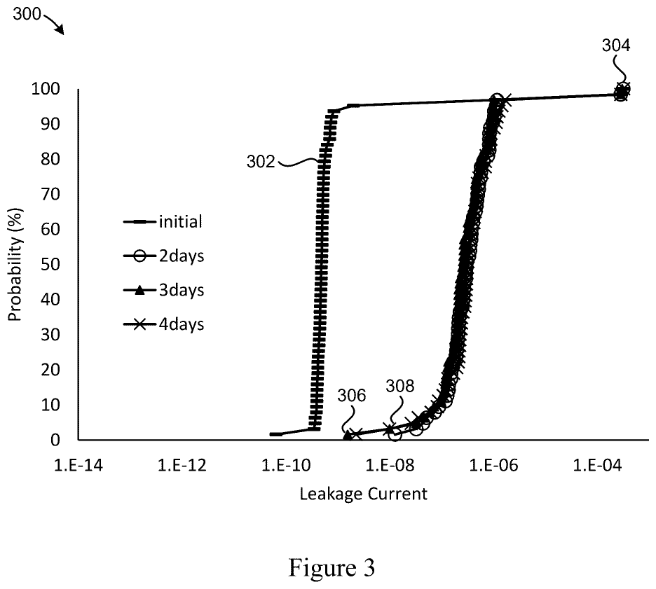

FIG. 3 illustrates a graph 300 showing a distribution of a leakage current along a semiconductor structure when no passivation layers are formed over metal and dielectric surfaces, in accordance with various embodiments. In particular, the graph 300 shows a probability percentage on the Y-axis against a leakage current on the X-axis.

The graph 300 includes multiple curves representing measurements taken at different time points after a chemical-mechanical polishing (CMP) process. Curve 302 (depicted using a dash as a data label) represents the initial leakage current distribution immediately following the CMP process, showing that approximately 90% of the measured locations have leakage currents around 1E-9 amperes or lower. This initial distribution indicates good electrical isolation between adjacent metal features in the semiconductor structure.

Curve 304 (depicted using an open circle as a data label) represents the leakage current distribution after the semiconductor structure has been allowed to sit for 2 days without any passivation layers. As shown in the graph 300, there is a significant shift of the curve 304 toward higher leakage currents, with the majority of measured locations showing leakage currents around 1E-7 amperes. This two-order-of-magnitude increase in leakage current demonstrates the rapid degradation of electrical properties that occurs when metal species from the metal surfaces diffuse onto adjacent dielectric surfaces.

Curves 306 (depicted using a filled triangle as a data label) and 308 (depicted using X as a data label) represent the leakage current distributions after 3 days and 4 days, respectively. These curves show further, though less dramatic, shifts toward higher leakage currents, indicating that the metal diffusion process continues but may begin to saturate after the initial rapid degradation. By day 4, as shown by the curve 308, the leakage current distribution appears to stabilize, suggesting that the diffusion of metal species reaches a saturation point. The data presented in graph 300 illustrates that without proper passivation the leakage current increases substantially within 2 days, which can lead to device failure or reliability issues.

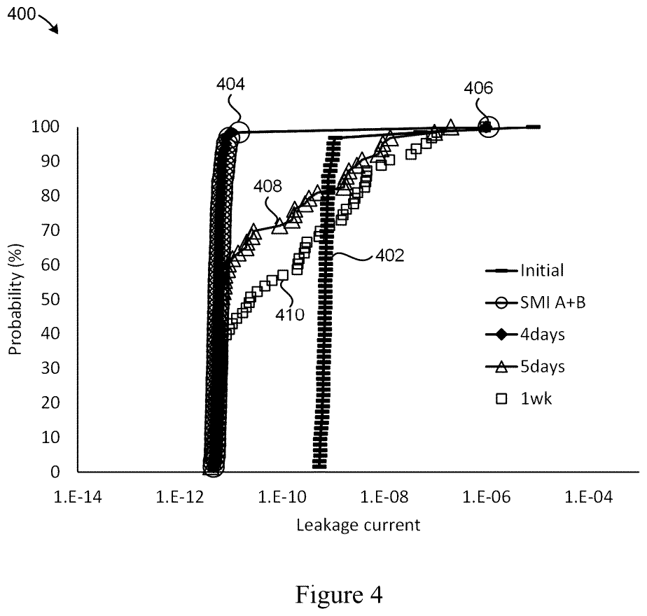

FIG. 4 illustrates a graph 400 showing a distribution of a leakage current along a semiconductor structure when passivation layers are formed over metal and dielectric surfaces, in accordance with various embodiments. In particular, the graph 400 shows a probability percentage on the Y-axis against a leakage current on the X-axis.

The graph 400 includes multiple curves representing measurements taken at different time points after the formation of passivation layers on the semiconductor structure. Curve 402 (depicted using a dash as a data label) represents the initial leakage current distribution following the CMP process before passivation, showing that approximately 90% of the measured locations have leakage currents around 1E-9 amperes or lower. This initial distribution indicates good electrical isolation between adjacent metal features in the semiconductor structure.

Curve 404 (depicted using an open circle as a data label) represents the leakage current distribution after the application of both the first inhibitor (denoted as SMI A in FIG. 4) on the metal surfaces and the second inhibitor (denoted SMI B in FIG. 4) on the dielectric surfaces, showing a significant improvement with leakage currents reduced to approximately 1E-11 amperes.

Curve 406 (depicted using a filled diamond as a data label) represents the leakage current distributions after 4 day, with the dual passivation layers in place. Unlike the unprotected structure shown in FIG. 3, the curve 406 demonstrates little to no shift toward higher leakage currents within 4 days. Curves 408 (depicted using an open triangle as a data label) and 410 (depicted using an open square as a data label) represent measurements after 5 days and 1 week, respectively, showing degradation of the leakage currents.

The data presented in graph 400 provides evidence of the effectiveness of the dual passivation approach. While the unpassivated structure in FIG. 3 shows a two-order-of-magnitude increase in leakage current after 2 days, the passivated structure maintains its electrical isolation properties for at least 4 days, showing signs of degradation after 5 days. Furthermore, data presented in graph 400 shows that at 1 week mark, majority of locations have a leakage current less than 1E-8 amperes.

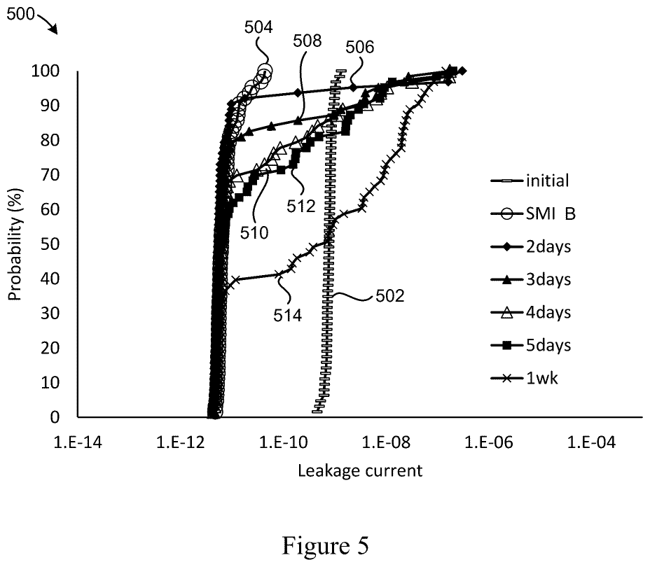

FIG. 5 illustrates a graph 500 showing a distribution of a leakage current along a semiconductor structure when a passivation layer is formed over a dielectric surface, in accordance with various embodiments. In particular, the graph 500 shows a probability percentage on the Y-axis against a leakage current on the X-axis.

The graph 500 includes multiple curves representing measurements taken at different time points during processing and storage. Curve 502 (depicted using a dash as a data label) represents the initial leakage current distribution following the CMP process before any passivation, showing leakage currents primarily concentrated around 1E-9 amperes. Curve 504 (depicted using an open circle as a data label) represents the leakage current distribution immediately after the application of both passivation layers (SMI A on the metal surfaces and SMI B on the dielectric surfaces) and removing the passivation layer (SMI A) from the metal surfaces, showing improvement with leakage currents reduced to approximately 1E-11 amperes.

Curves 506 (depicted using a filled diamond as a data label), 508 (depicted using a filled triangle as a data label), 510 (depicted using an open triangle as a data label), 512 (depicted using a filled square as a data label), and 514 (depicted using X as a data label) represent the leakage current distributions after 2 days, 3 days, 4 days, 5 days, and 1 week, respectively, with the passivation layers maintained over the dielectric surfaces.

As shown by curve 506, after 2 days a small percentage of measurement locations (approximately 10%) begin to show increased leakage current, while the majority remain protected. Curves 508 and 510 demonstrate that after 3 and 4 days, the degradation continues progressively, with more locations showing elevated leakage currents. By 5 days (curve 512) and 1 week (curve 514), a significant portion of the measurement locations show increased leakage current, though the degradation remains less severe than for the completely unprotected structure shown in FIG. 3.

The data presented in graph 500 provides valuable insights into the relative contributions of the two passivation layers. While the dual passivation approach shown in FIG. 4 provides the better protection, maintaining only the dielectric surface passivation (SMI B) still offers improvement over no passivation at all. This intermediate level of protection may be sufficient for processes where shorter queue times are acceptable, and there are specific requirements for having an exposed metal surface. Furthermore, data presented in graph 500 shows that at 5 day mark, majority of locations have a leakage current less than 1E-8 amperes.

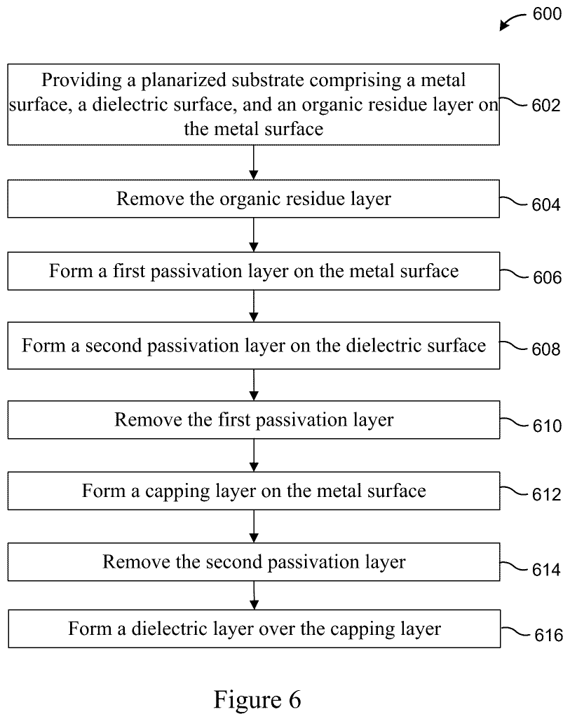

FIG. 6 illustrates a flow diagram of a method 600 for passivating a post-planarization surface of a semiconductor structure, in accordance with various embodiments. The method 600 may be performed to enhance queue time control and prevent metal diffusion in semiconductor manufacturing processes. Although shown in a particular sequence, it should be appreciated that the steps of the method 600 may be performed in any suitable sequence.

The method 600 starts with step 602 when a planarized substrate (e.g., semiconductor structure 100 of FIG. 1A) is provided as described above with reference to FIG. 1A. In some embodiments, the planarized substrate may comprise a metal surface (e.g., metal surface 112s of FIG. 1A), a dielectric surface (e.g., dielectric surface 106s of FIG. 1A), and an organic residue layer (e.g., organic residue layer 114 of FIG. 1A) on the metal surface.

In step 604, the organic residue layer is removed from the metal surface as described above with reference to FIG. 1B. In step 606, a first passivation layer (e.g., passivation layer 118 of FIG. 1C) is formed on the metal surface as described above with reference to FIG. 1C. In step 608, a second passivation layer (e.g., passivation layer 120 of FIG. 1D) is formed on the dielectric surface as described above with reference to FIG. 1D.

In step 610, the first passivation layer is removed from the metal surface as described above with reference to FIG. 1E. In step 612, a capping layer (e.g., capping layer 122 of FIG. 1F) is formed on the metal surface as described above with reference to FIG. 1F. In step 614, the second passivation layer is removed from the dielectric surface as described above with reference to FIG. 1G. In step 616, a dielectric layer (e.g., etch stop layer 124 of FIG. 1H) is formed over the capping layer and the dielectric surface as described above with reference to FIG. 1H.

Example 1. A method including: providing a substrate including a metal surface and a dielectric surface in at least substantially a same horizontal plane; treating the substrate with a first inhibitor, the first inhibitor covering the metal surface; treating the substrate with a second inhibitor, the second inhibitor covering the dielectric surface; and removing the first inhibitor from the metal surface of the substrate.

Example 2. The method of example 1, further including: selectively depositing a capping layer on the metal surface; removing the second inhibitor from the dielectric surface; and forming a dielectric layer over the capping layer and the dielectric surface.

Example 3. The method of any of examples 1 and 2, further including removing the second inhibitor from the dielectric surface.

Example 4. The method of any of examples 1 to 3, where a first inhibitor covered metal surface and a second inhibitor covered dielectric surface prevent diffusion of oxidized metal from the metal surface onto the dielectric surface while waiting for further processing of the substrate.

Example 5. The method of any of examples 1 to 4, where the first inhibitor includes small molecular inhibitor (SMI) or a first precursor for a self-assembled monolayer.

Example 6. The method of example 5, where the first inhibitor includes a nitrogen-containing compound.

Example 7. The method of example 6, where the nitrogen-containing compound includes NH₃, N₂H₄, or an aromatic compound.

Example 8. The method of example 7, where the aromatic compound includes pyridine, pyrimidine, pyrazine, pyrrole, imidazole, pyrazole, aniline, or benzotriazole (BTA).

Example 9. The method of example 5, where the first inhibitor includes R—PO₃H, R—COOH, R—SH, or R—SOₓ.

Example 10. The method of example 5, where the first inhibitor includes 1-octadecanethiol (CH₃(CH₂)₁₆CH₂SH), perfluorodecyltrichlorosilane (CF₃(CF₂)₇CH₂CH₂SiCl₃), perfluorodecanethiol (CF₃(CF₂)₇CH₂CH₂SH), chlorodecyldimethylsilane (CH₃(CH₂)₈CH₂Si(CH₃)₂Cl), or tertbutyl(chloro)dimethylsilane ((CH₃)₃CSi(Cl)(CH₃)₂)).

Example 11. The method of example 5, where the first inhibitor includes a non-heterocyclic carbene or a thiol.

Example 12. The method of any of examples 1 to 11, where the second inhibitor includes a second small molecular inhibitor (SMI) or a second precursor for a self-assembled monolayer.

Example 13. The method of example 12, where the second inhibitor includes an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, dimethylsilane dimethylamine (DMSDMA), trimethylsilane dimethylamine (TMSDMA), bis(dimethylamino) dimethylsilane (BDMADMS), N,O bistrimethylsilyltrifluoroacetamide (BSTFA), or trimethylsilyl-pyrrole (TMS-pyrrole).

Example 14. The method of any of examples 1 to 13, where the metal surface includes Cu, Al, Ta, Ti, W, Ru, Co, Ni, Mn, Nb, or Mo.

Example 15. The method of any of examples 1 to 14, where the dielectric surface includes SiO₂ or a low-k material.

Example 16. A method including: providing a substrate including a metal surface and a dielectric surface in at least substantially a same horizontal plane, the metal surface including an organic residue from a planarization process; removing the organic residue from the metal surface; forming a first passivation layer over the substrate, the first passivation layer covering the metal surface; forming a second passivation layer over the substrate, the second passivation layer covering the dielectric surface, where a first passivation layer covered metal surface and a second passivation layer covered dielectric surface prevent diffusion of oxidized metal from the metal surface onto the dielectric surface while waiting for further processing of the substrate; and removing the first passivation layer from the metal surface.

Example 17. The method of example 16, where the organic residue includes 1,2,3 Benzotriazole (BTA).

Example 18. The method of any of examples 16 and 17, where removing the organic residue from the metal surface includes annealing the substrate in a gas mixture including argon (Ar) and hydrogen (H₂), or a gas mixture including nitrogen (N₂) and ammonia (NH₃).

Example 19. The method of any of examples 16 to 18, where removing the first passivation layer from the metal surface of the substrate include annealing the substrate in a gas mixture including hydrogen (H₂).

Example 20. The method of any of examples 16 to 19, further including removing the second passivation layer from the dielectric surface by exposing the second passivation layer to an ultraviolet (UV) radiation or a plasma.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
providing a substrate comprising a metal surface and a dielectric surface in at least substantially a same horizontal plane;
treating the substrate with a first inhibitor, the first inhibitor covering the metal surface;
treating the substrate with a second inhibitor, the second inhibitor covering the dielectric surface; and
removing the first inhibitor from the metal surface of the substrate.

2. The method of claim 1, further comprising:
selectively depositing a capping layer on the metal surface;
removing the second inhibitor from the dielectric surface; and
forming a dielectric layer over the capping layer and the dielectric surface.

3. The method of claim 1, further comprising:
removing the second inhibitor from the dielectric surface.

4. The method of claim 1, wherein a first inhibitor covered metal surface and a second inhibitor covered dielectric surface prevent diffusion of oxidized metal from the metal surface onto the dielectric surface while waiting for further processing of the substrate.

5. The method of claim 1, wherein the first inhibitor includes small molecular inhibitor (SMI) or a first precursor for a self-assembled monolayer.

6. The method of claim 5, wherein the first inhibitor comprises a nitrogen-containing compound.

7. The method of claim 6, wherein the nitrogen-containing compound comprises NH₃, N₂H₄, or an aromatic compound.

8. The method of claim 7, wherein the aromatic compound comprises pyridine, pyrimidine, pyrazine, pyrrole, imidazole, pyrazole, aniline, or benzotriazole (BTA).

9. The method of claim 5, wherein the first inhibitor comprises R—PO₃H, R—COOH, R—SH, or R—SOₓ.

10. The method of claim 5, wherein the first inhibitor comprises 1-octadecanethiol (CH₃(CH₂)₁₆CH₂SH), perfluorodecyltrichlorosilane (CF₃(CF₂)₇CH₂CH₂SiCl₃), perfluorodecanethiol (CF₃(CF₂)₇CH₂CH₂SH), chlorodecyldimethylsilane (CH₃(CH₂)₈CH₂Si(CH₃)₂Cl), or tertbutyl(chloro)dimethylsilane ((CH₃)₃CSi(Cl)(CH₃)₂)).

11. The method of claim 5, wherein the first inhibitor comprises a non-heterocyclic carbene or a thiol.

12. The method of claim 1, wherein the second inhibitor includes a second small molecular inhibitor (SMI) or a second precursor for a self-assembled monolayer.

13. The method of claim 12, wherein the second inhibitor comprises an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, dimethylsilane dimethylamine (DMSDMA), trimethylsilane dimethylamine (TMSDMA), bis(dimethylamino) dimethylsilane (BDMADMS), N,O bistrimethylsilyltrifluoroacetamide (BSTFA), or trimethylsilyl-pyrrole (TMS-pyrrole).

14. The method of claim 1, wherein the metal surface comprises Cu, Al, Ta, Ti, W, Ru, Co, Ni, Mn, Nb, or Mo.

15. The method of claim 1, wherein the dielectric surface comprises SiO₂ or a low-k material.

16. A method comprising:
providing a substrate comprising a metal surface and a dielectric surface in at least substantially a same horizontal plane, the metal surface comprising an organic residue from a planarization process;
removing the organic residue from the metal surface;
forming a first passivation layer over the substrate, the first passivation layer covering the metal surface;
forming a second passivation layer over the substrate, the second passivation layer covering the dielectric surface, wherein a first passivation layer covered metal surface and a second passivation layer covered dielectric surface prevent diffusion of oxidized metal from the metal surface onto the dielectric surface while waiting for further processing of the substrate; and
removing the first passivation layer from the metal surface.

17. The method of claim 16, wherein the organic residue comprises 1,2,3 Benzotriazole (BTA).

18. The method of claim 16, wherein removing the organic residue from the metal surface comprises annealing the substrate in a gas mixture comprising argon (Ar) and hydrogen (H₂), or a gas mixture comprising nitrogen (N₂) and ammonia (NH₃).

19. The method of claim 16, wherein removing the first passivation layer from the metal surface of the substrate comprises annealing the substrate in a gas mixture comprising hydrogen (H₂).

20. The method of claim 16, further comprising removing the second passivation layer from the dielectric surface by exposing the second passivation layer to an ultraviolet (UV) radiation or a plasma.
